(19) United States
(12) Patent Application Publication
(10) Pub. No.: US 2012/0255492 A1
(43) Pub. Date: Oct. 11, 2012

(54) Large Area Atmospheric Pressure Plasma Enhanced Chemical Vapor Deposition Apparatus

(75) Inventors: Mien-Win Wu, Taoyuan County (TW); Ding-Guey Tsai, Taoyuan County (TW); Hwei-Lang Chang, Taoyuan County (TW); Deng-Lain Lin, Taoyuan County (TW); Cheng-Chang Hsieh, Chiayi City (TW); Chi-Fong Ai, Taoyuan County (TW)

(73) Assignee: ATOMIC ENERGY COUNCIL-INSTITUTE OF NUCLEAR ENETGY RESEARCH, Taoyuan County (TW)

(21) Appl. No.: 13/080,874

(22) Filed: Apr. 6, 2011

(51) Int. Cl. C23C 16/513; C23C 16/458; C23C 16/50; C23C 16/453

(52) U.S. Cl. 118/723 E

(57) ABSTRACT

An apparatus provides large area atmospheric pressure plasma enhanced chemical vapor deposition without contaminations in its electrode assembly and deposited films. The apparatus consists of a large area vertical planar nitrogen plasma activation electrode assembly and its high voltage power supply, a large area vertical planar nitrogen plasma deposition electrode assembly and its high voltage power supply, a long-line uniform precursor jet apparatus, a roll-to-roll apparatus for substrate movement, and a sub-atmospheric pressure deposition chamber and its pumping apparatus. Not only can the deposited film contaminations in the electrode assembly interior and the debris of the deposited films from exterior of the electrode assembly and the air aerosols in the deposition chamber be completely prevented, but a large area roll-to-roll uniform deposition can also be achieved to meet a roll-to-roll continuous production, so as to achieve improved film quality, increased production throughput and reduced manufacturing cost.

### BACKGROUND OF INVENTION

1. Field of Invention

The present invention relates to an apparatus for large area atmospheric pressure plasma enhanced chemical vapor deposition without contaminations on electrode assemblies and deposited films and, more particularly, to an apparatus for atmospheric pressure plasma enhanced chemical vapor deposition on a roll of substrate.

2. Related Prior Art

Plasma includes highly active species such as high-energy electrons, ions, free radicals and ultraviolet light. Vacuum plasma has been used in highly value-added process for making semiconductor products such as etching and deposition since 30 years ago. Vacuum plasma however requires an expensive vacuum chamber and an expensive pump. To reduce the cost of the equipment and the cost of the product, atmospheric pressure plasma devices and related processes have been developed since 20 years ago.

An atmospheric pressure plasma process does not require an expensive vacuum chamber. The area of a substrate to be processed in an atmospheric pressure plasma process is not limited by any vacuum chamber. These are two advantages over a vacuum plasma process. Atmospheric pressure plasma enhanced chemical vapor deposition (PECVD) is often used to make highly value-added products such as an anti-scratch plastic lens, an anti-reflection film of a display of a personal digital assistant (PDA), a cell phone or a digital camera, an anti-erosion film on metal, and an air-tight layer of polymer. Atmospheric pressure PECVD can be used for encapsulating a light, tiny and flexible electronic product such as an organic light-emitting diode (OLED), a thin-film cell, an organic solar cell, an inorganic solar cell and an LED/LED. Therefore, a lot of efforts have been made on atmospheric pressure PECVD and can be found in various documents. For example, R. Morent et al of Ghent University published an essay in Progress in Organic Depositions, 2009, and S. Martin et al of LGET-UPS published another essay in Surface and Deposition Technology, 2004. The techniques discussed in these documents are however difficult. Hence, there has not been devised any commercially available device related thereto.

Referring to FIG. 14, there is shown a conventional atmospheric pressure PECVD assembly 5. Details of this conventional atmospheric pressure PECVD assembly 5 can be found in WO03086031 A1 filed by Andrew James Goodwin et al in 2003. This conventional atmospheric pressure PECVD assembly 5 includes at least one pair of atmospheric pressure plasma sources 51 and 52, a sprayer 53 for spraying precursor, three rollers 54, 55 and 56 for conveying a roll of substrate, and a plasma gas inlet 57. The pair of atmospheric pressure plasma sources 51 and 52 includes planar dielectric electrode assemblies and produces atmospheric pressure plasma using helium gas. The first plasma source 51 includes two electrode assemblies 51a and 51b. The first plasma source 51 produces plasma for cleaning and activating the substrate. The second plasma source 52 includes two electrode assemblies 52a and 52b. The sprayed precursor is mixed with helium gas before the mixture is fed into a gap defined between the electrode assemblies 52a and 52b of the second plasma source 52. Several problems are however encountered in the use of this conventional atmospheric pressure PECVD assembly 5. At first, although a portion of the decomposed precursor is deposited on the substrate, inevitably another portion of the decomposed precursor is also deposited simultaneously on the inside of the electrode assemblies, thus changing the properties of the generated plasma rapidly. Hence, the operation of this conventional atmospheric pressure PECVD assembly 5 has to be shut down often for cleaning the contaminated electrode assembly, thus rendering continuous operation impossible. Secondly, the helium gas is contaminated with sprayed precursor which can not be electrically discharged easily as helium gas, thus the density of generated plasma is reduced considerably, resulting in lower deposition rates. Thirdly, expensive helium gas is used as the plasma gas, thus rendering the manufacturing cost high.

Referring to FIG. 15, there is shown another conventional atmospheric-pressure PECVD reactor 6. Details of this conventional atmospheric-pressure PECVD reactor 6 can be found in US 20090162263 A1 filed by Chia-Chiang Chang et al in 2009. The conventional atmospheric-pressure PECVD reactor 6 includes a high-frequency power supply 330, a high-voltage metal electrode assembly 310 for evenly distributing a precursor, an isolative shell 350 for evenly distributing plasma gas, and a grounded metal electrode assembly 320 used as a nozzle for the plasma and the decomposed precursor. The high-voltage metal electrode assembly 310 includes nozzles P1 for spraying the precursor, a conduit S4 for conveying the precursor, and a precursor-distributing plate 364 including a plurality of apertures defined therein. The grounded metal electrode assembly 320 includes nozzles P2 for spraying the decomposed precursor after the interaction with the plasma. The isolative shell 350 includes a plurality of inlets P3 for feeding the plasma gas. The isolative shell 350 is connected the grounded metal electrode assembly 320 and high-voltage metal electrode assembly 310, with a space S5 defined between them. Two plasma gas-distributing plates 362 are located in the space S5. Each of the plasma gas-distributing plates 362 includes apertures P4 defined therein. Problems are however encountered in the use of this conventional atmospheric pressure PECVD reactor 6. At first, the precursor is decomposed by the plasma between the high-voltage metal electrode assemblies 310 and the grounded metal electrode assembly 320. Thus, a portion of the decomposed precursor is inevitably deposited inside the metal electrode assemblies 310 and the inside of the grounded metal electrode assembly 320, and the properties of the plasma and the deposition performance varied accordingly. Therefore, the operation of this conventional atmospheric pressure PECVD reactor 6 must be shut-down often for cleaning the metal electrode assemblies and the grounded metal electrode assembly, thus rendering continuous operation impossible. Secondly, the helium gas in the neighborhood of nozzles P1 is diluted considerably by the sprayed precursor is, thus reducing the density of the plasma and the deposition rate. Thirdly, expensive helium gas is used as the plasma gas, thus rendering the manufacturing cost high.

As discussed above, these two conventional atmospheric pressure PECVD devices exhibit two major common disadvantages. That is, the manufacturing cost of the plasma is high because expensive helium gas is used. Secondly, continuous production of the PECVD is impossible because a portion of the precursor is inevitably deposited on the electrode assemblies and they have to be shut down often for cleaning their electrode assemblies. Although these conventional atmospheric pressure PECVD devices can be used to coat flexible substrates, they are not economic.

The present invention is therefore intended to obviate or at least alleviate the problems encountered in prior art.

### SUMMARY OF INVENTION

It is an objective of the present invention to provide an apparatus for large area atmospheric pressure plasma enhanced chemical vapor deposition on a roll of substrate.

It is another objective of the present invention to provide an apparatus for large area atmospheric pressure plasma enhanced chemical vapor deposition on a roll of substrate while preventing fragments of the deposition and aerosols in the deposition chamber from falling on the substrate or the films of deposition on the inner surfaces of electrode assemblies.

It is another objective of the present invention to provide an apparatus for continuous large area atmospheric pressure plasma enhanced chemical vapor deposition on a roll of substrate.

To achieve the foregoing objectives, the large area atmospheric pressure PECVD apparatus includes a sub-atmospheric pressure deposition chamber, at least one large area vertical planar atmospheric pressure nitrogen gas (N₂) plasma activation electrode assembly, at least one large area vertical planar atmospheric pressure N₂ plasma deposition electrode assembly, at least one long-line uniform precursor distributor and a roll-to-roll substrate conveyor. The sub-atmospheric pressure deposition chamber includes a vent defined therein and a pump operable for pumping gas from the sub-atmospheric pressure deposition chamber through the vent to create a sub-atmospheric pressure condition in the sub-atmospheric pressure deposition chamber. The large area vertical planar atmospheric pressure plasma activation electrode assembly is located in the sub-atmospheric pressure deposition chamber and connected to a high voltage power supply located outside the sub-atmospheric pressure deposition chamber. The large area vertical planar atmospheric pressure plasma deposition electrode assembly is located in the sub-atmospheric pressure deposition chamber and connected to a high voltage power supply located outside the sub-atmospheric pressure deposition chamber. The roll-to-roll substrate conveyor is located in the sub-atmospheric pressure deposition chamber for conveying the substrate so that the first vertical section of the substrate travels past the large area vertical planar atmospheric pressure plasma activation electrode assembly while a second vertical section of the substrate travels past the large area vertical planar atmospheric pressure plasma deposition electrode assembly. The precursor distributor is located in the sub-atmospheric pressure deposition chamber between the large area vertical planar atmospheric pressure plasma deposition electrode assembly and a second vertical section of a substrate and connected to a precursor provider located outside the sub-atmospheric pressure deposition chamber.

In another aspect, each of the large area vertical planar atmospheric pressure plasma activation and deposition electrode assemblies includes a grounded and sealed rectangular metal chamber, a grounded planar electrode located on the rectangular metal chamber, a water-cooled planar high voltage electrode located in the rectangular metal chamber, and two uniform plasma gas distributors located above and below the planar high voltage electrode, respectively.

In another aspect, the planar high voltage electrode includes a rectangular metal plate, an aluminum oxide ceramic dielectric plate attached to a rectangular metal plate, a plastic coolant tank located around and attached to the aluminum oxide ceramic dielectric plate, a high voltage connecting rod inserted through the plastic coolant tank and connected to the metal plate, a high voltage isolative sleeve located around the high voltage connecting rod, and a coolant channel defined in the plastic coolant tank.

In another aspect, the rectangular metal chamber includes coolant inlet and outlet defined therein and two plasma gas inlet pipes inserted therein.

In another aspect, the grounded planar electrode includes a metal plate with a plasma spraying orifice array evenly defined therein, a plurality of aluminum oxide ceramic pads attached to the metal plate around the plasma spraying orifice array, and a plurality of apertures or screw holes defined in the metal plate for receiving fasteners such as screws for attaching the metal plate to the rectangular metal chamber.

In another aspect, the plasma spraying orifice array includes at least two plasma spraying orifice groups each including several plasma spraying orifice rows. Transverse projections of the plasma spraying orifice rows are continuous or overlapped one another in each of the plasma spraying orifice groups.

The plasma spraying orifice array may include two plasma spraying orifice groups. The plasma spraying orifice groups are transversely shifted from each other by ½ of the diameter d of the plasma spraying orifices.

Alternatively, the plasma spraying orifice array may include three plasma spraying orifice groups. Any two adjacent ones of the plasma spraying orifice groups are transversely shifted from each other by ⅓ of the diameter d of the plasma spraying orifices.

In another aspect, each of the plasma gas distributors includes a flat shell and four plasma gas dividers. The flat shell includes a plasma gas inlet defined in a side, a plasma gas outlet defined in an opposite side, and a plasma gas mixing and distributing section defined therein near the plasma gas outlet. The first plasma gas divider is located in the flat rectangular shell for dividing plasma gas to two streams. The second plasma gas divider is located in the flat rectangular shell for dividing the plasma gas into four streams. The third plasma gas divider is located in the flat rectangular shell for dividing the plasma gas into eight streams. The fourth plasma gas divider is located in the flat rectangular shell for dividing plasma gas into sixteen streams.

In another aspect, each of the plasma gas distributors includes a high voltage isolative plate located beneath or on the plasma gas mixing and distributing section and two plasma gas guiding plates and located on two opposite sides of the plasma gas outlet.

In another aspect, the precursor distributor includes a flat shell and four precursor dividers. The flat shell includes a precursor inlet defined in a side, a precursor outlet defined in an opposite side, and a flat precursor mixing and distributing section defined therein near the precursor outlet. The first precursor divider is located therein for dividing precursor into two streams. The second precursor divider is located therein for dividing the precursor into four streams. The third precursor divider is located therein for dividing the precursor into eight streams. The fourth precursor divider is located therein for dividing the precursor into sixteen streams.

In another aspect, the roll-to-roll substrate conveyor includes a first reel located near the large area vertical planar atmospheric pressure plasma activation electrode assembly, a second reel located near the large area vertical planar atmospheric pressure plasma deposition electrode assembly, a first positioning roller located above the first reel, a second positioning roller located above the second reel, an IR heater located between the second reel and the second positioning roller.

In another aspect, each of the high voltage power supplies may be a pulse power supply, AC sine-wave power supply or a high power RF power supply operated at 1 to 100 kHz.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a schematic diagram of the apparatus for large area atmospheric pressure N₂ plasma enhanced chemical vapor deposition on a roll of substrate according to the preferred embodiment of the present invention;

FIG. 2 is a cross-sectional view of the center of shorter side of the vertical planar electrode assembly of the apparatus for large area atmospheric pressure N₂ plasma activation and for large area atmospheric pressure N₂ plasma enhanced chemical vapor deposition on a roll of substrate shown in FIG. 1;

FIG. 3 is a cross-sectional view of the center of longer side of the vertical planar electrode assembly of the apparatus for large area atmospheric pressure N₂ plasma activation and for large area atmospheric pressure N₂ plasma enhanced chemical vapor deposition on a roll of substrate shown in FIG. 1;

FIG. 4 is a cross-sectional view of the plasma gas confinement plate of shorter side of the vertical planar electrode assembly of the apparatus for large area atmospheric pressure N₂ plasma activation and for large area atmospheric pressure N₂ plasma enhanced chemical vapor deposition on a roll of substrate shown in FIG. 1;

FIG. 5 is a cross-sectional view of the vertical planar electrode assembly along a line g-h shown in FIG. 2;

FIG. 6 is a schematic diagram of an uniform plasma gas nozzle assembly of the electrode assembly shown in FIG. 2;

FIG. 7 is a cross-sectional view of the uniform plasma gas nozzle assembly along a line a-b shown in FIG. 6;

FIG. 8 is a cross-sectional view of the uniform plasma nozzle assembly along a line c-d shown in FIG. 6;

FIG. 9 is a schematic diagram of a long-line uniform precursor nozzle assembly of the apparatus for atmospheric pressure N₂ plasma enhanced chemical vapor deposition on a roll of substrate shown in FIG. 1;

FIG. 10 is a cross-sectional view of the long-line uniform precursor nozzle assembly along a line e-f shown in FIG. 9;

FIG. 11 is a cross-sectional view of the long-line uniform precursor nozzle assembly along a line i-j shown in FIG. 9;

FIG. 12 is a schematic diagram of a roll-to-roll substrate conveying unit of the apparatus for atmospheric pressure N₂ plasma enhanced chemical vapor deposition on a roll of substrate shown in FIG. 1;

FIG. 13 is a schematic diagram of the distribution of a uniform plasma nozzles of the grounded planar electrode of the electrode assembly shown in FIG. 2;

FIG. 14 is a schematic diagram of a conventional atmospheric pressure PECVD assembly; and

FIG. 15 is a schematic diagram of another conventional atmospheric-pressure PECVD reactor.

### DETAILED DESCRIPTION OF PREFERRED EMBODIMENT

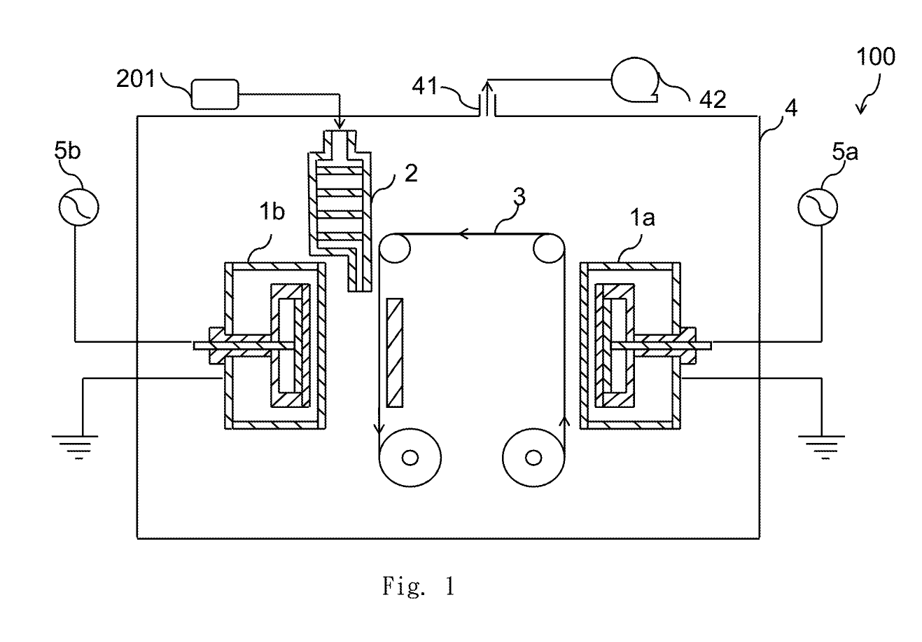

Referring to FIG. 1, there is shown an apparatus 100 for large area atmospheric pressure N₂ plasma enhanced chemical vapor deposition on a roll of substrate according to the preferred embodiment of the present invention. The apparatus 100 includes at least one large area vertical planar atmospheric pressure N₂ plasma activation electrode assembly 1a, at least one large area vertical planar atmospheric pressure N₂ plasma deposition electrode assembly 1b, at least one precursor distributor 2, a roll-to-roll substrate conveyor 3 and a sub-atmospheric pressure deposition chamber 4.

The large area vertical planar atmospheric pressure N₂ plasma activation electrode assembly 1a and the large area vertical planar atmospheric pressure N₂ plasma deposition electrode assembly 1b are located in the sub-atmospheric pressure deposition chamber 4. A high voltage power supply 5a is located outside the sub-atmospheric pressure deposition chamber 4. The high voltage power supply 5a is electrically connected to the large area vertical planar atmospheric pressure N₂ plasma activation electrode assembly 1a to produce N₂ plasma to activate substrate for promoting adhesion of deposited films. A high voltage power supply 5b is located outside the sub-atmospheric pressure deposition chamber 4. The high voltage power supply 5a is electrically connected to the large area vertical planar atmospheric pressure N₂ plasma deposition electrode assembly 1b to produce N₂ plasma for coating the substrate. The high voltage power supplies 5a and 5b provides high voltage pulses, AC sine-waves or high power RF at 1 to 100 kHz.

The roll-to-roll substrate conveyor 3 is also located in the sub-atmospheric pressure deposition chamber 4. The roll-to-roll substrate conveyor 3 continuously conveys the substrate so that a first vertical section of the substrate travels in a plasma activation zone near the large vertical area planar atmospheric pressure N₂ plasma activation electrode assembly 1a while a second vertical section of the substrate travels in a plasma deposition zone near the large area vertical planar atmospheric pressure N₂ plasma deposition electrode assembly 1b. In the N₂ plasma activation zone, the first vertical section of the substrate travels parallel to the large area vertical planar atmospheric pressure N₂ plasma activation electrode assembly 1a, with a gap of 2 to 4 mm defined between them. In the N₂ plasma deposition zone, the second vertical section of the substrate travels parallel to the large area vertical planar atmospheric pressure N₂ plasma deposition electrode assembly 1b, with a gap of 6 to 10 mm defined between them.

The long-line uniform precursor distributor 2 is also located in the sub-atmospheric pressure deposition chamber 4. The long-line uniform precursor distributor 2 is preferably located above a gap defined between the large area vertical planar atmospheric pressure N₂ plasma deposition electrode assembly 1b and the second vertical section of the substrate. The long-line uniform precursor distributor 2 is connected to a precursor provider 201 located outside the sub-atmospheric pressure deposition chamber 4 to evenly distribute gaseous precursor so that the gaseous precursor travels parallel to and between the large area vertical planar atmospheric pressure N₂ plasma deposition electrode assembly 1b and the second vertical section of the substrate.

The sub-atmospheric pressure deposition chamber 4 includes a vent 41 defined in an upper portion for example. A pump 42 is located on the sub-atmospheric pressure deposition chamber 4. The pump 42 is in communication with the sub-atmospheric pressure deposition chamber 4 through the vent 41. The pump 42 is operated to pump used plasma gas and decomposed precursor not deposited on the substrate out of the sub-atmospheric pressure deposition chamber 4 through the vent 41 to provide a sub-atmospheric pressure condition in the sub-atmospheric pressure deposition chamber 4 to prevent the gaseous precursor from entering the environment around the sub-atmospheric pressure deposition chamber 4.

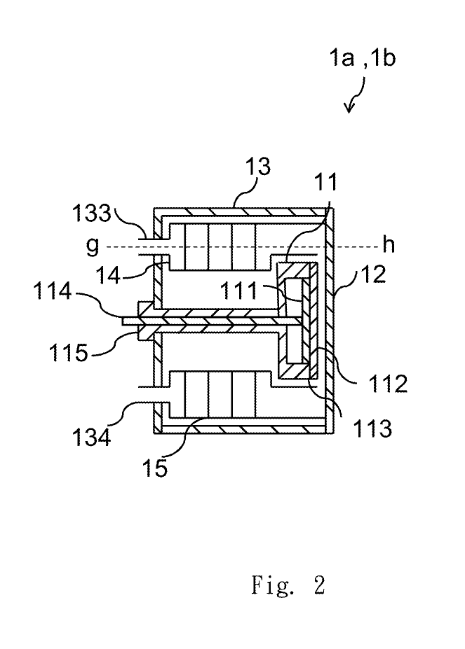

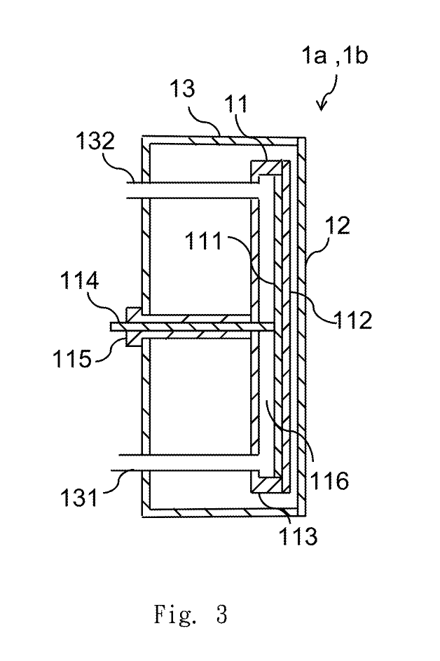

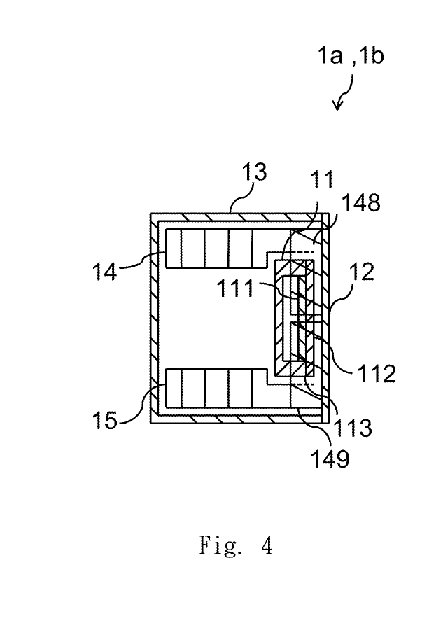

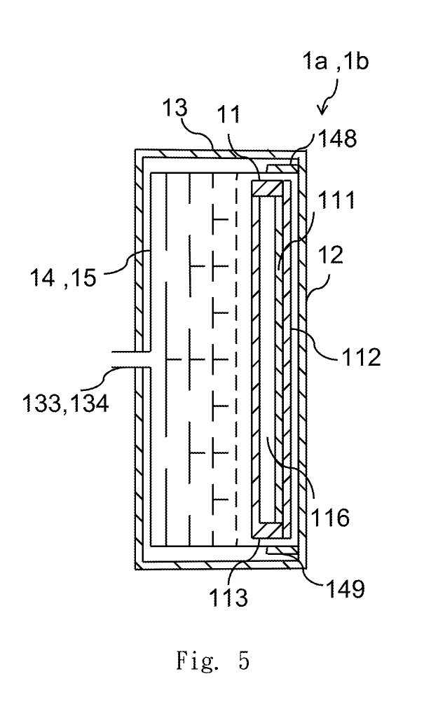

Referring to FIGS. 2 to 5, the large area vertical planar atmospheric pressure N₂ plasma activation electrode assembly 1a is structurally identical to the large area vertical planar atmospheric pressure N₂ plasma deposition electrode assembly 1b. Each of the large area vertical planar atmospheric pressure plasma activation electrode assembly 1a and the large area vertical planar atmospheric pressure N₂ plasma deposition electrode assembly 1b includes a grounded and sealed rectangular metal chamber 13, a grounded planar electrode 12 located on the rectangular metal chamber 13, a water-cooled planar high voltage electrode 11 located in the rectangular metal chamber 13, and two uniform plasma gas distributors 14 and 15 located above and below the planar high voltage electrode 11, respectively.

The planar high voltage electrode 11 includes a rectangular metal plate, an aluminum oxide ceramic dielectric plate 112 attached to a rectangular metal plate 111, a plastic coolant tank 113 located around and attached to the aluminum oxide ceramic dielectric plate 112, a high voltage connecting rod 114 inserted through the plastic coolant tank 113 and connected to the metal plate 111, a high voltage isolative sleeve 115 located around the high voltage connecting rod 114, and a coolant channel 116 defined in the plastic coolant tank 113.

The rectangular metal chamber 13 includes a coolant inlet 131, a coolant outlet 132, and two plasma gas inlet pipes 133 and 134. The coolant inlet 131 and the coolant outlet 132 are located on two opposite sides of the planar high voltage electrode 11. The uniform plasma gas inlet pipes 133 and 134 are located above and below the planar high voltage electrode 11, respectively.

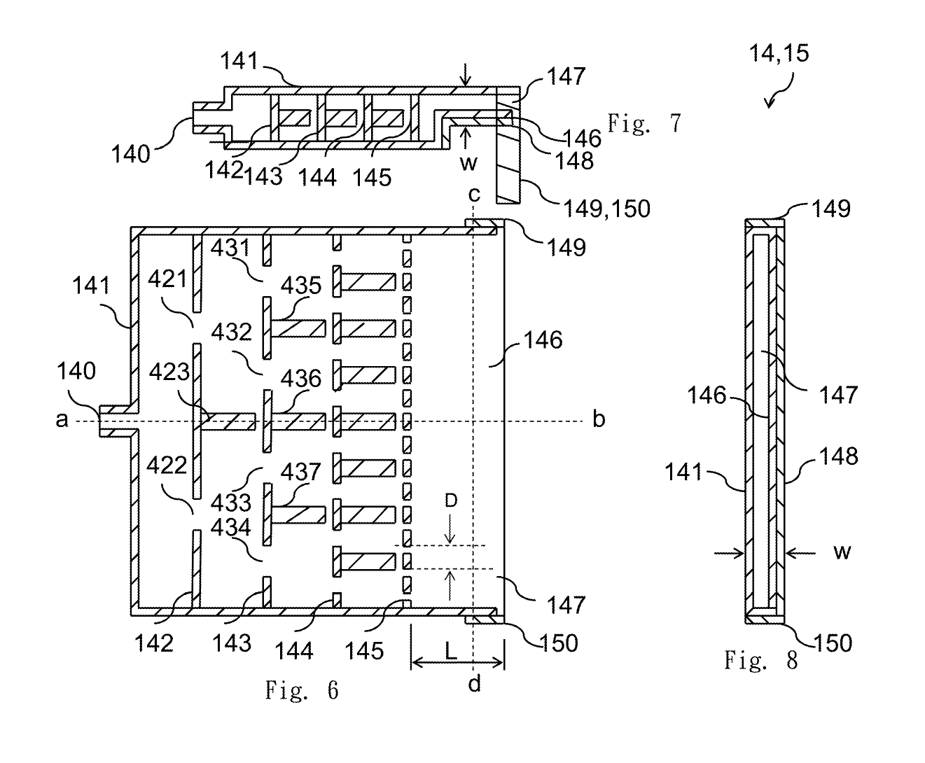

Referring to FIGS. 6 to 8, the uniform plasma gas distributors 14 and 15 are structurally identical to each other. Each of the uniform plasma gas distributors 14 and 15 includes a flat rectangular box 141, a first-grade plasma gas divider 142, a second-grade plasma gas divider 143, a third-grade plasma gas divider 143 and a fourth-grade plasma gas divider 145. The rectangular box 141 includes a plasma gas inlet 140 defined in a side, a flat plasma gas outlet 147 defined in an opposite side, a plasma gas uniformly mixing and distributing section 146 defined therein near the plasma gas outlet 147. All of the first-grade plasma gas divider 142, the second-grade plasma gas divider 143, the third-grade plasma gas divider 143 and the fourth-grade plasma gas divider 145 are sequentially located in the flat rectangular box 141 between the inlet 140 and the plasma gas uniformly mixing and distributing section 146.

The first-grade plasma gas divider 142 includes two identical apertures 421 and 422 defined therein and a plasma gas dividing partition 423 formed thereon. The plasma gas dividing partition 423 is located between the apertures 421 and 422.

The second-grade plasma gas divider 143 includes four identical apertures 431, 432, 433 and 434 defined therein and three identical plasma gas dividing partitions 435, 436 and 437 formed thereon. Each of the plasma gas dividing partitions 435, 436 and 437 is located between two related ones of the apertures 431, 432, 433 and 434.

The third-grade plasma gas divider 144 includes eight identical apertures and seven identical plasma gas dividing partitions formed thereon. The apertures defined in the third-grade plasma gas divider 144 are not numbered for the clarity of the drawings; however, they are identical to or smaller than the apertures 421, 422 and 431 to 434. The plasma gas dividing partitions formed on the third-grade plasma gas divider 144 are not numbered for the clarity of the drawings; however, they are identical to the plasma gas dividing partitions 423 and 435 to 437. Similarly, each of the plasma gas dividing partitions formed on the third-grade plasma gas divider 144 is located between two related ones of the apertures defined in the third-grade plasma gas divider 144.

The fourth-grade plasma gas divider 145 includes sixteen identical apertures defined therein. The apertures defined in the fourth-grade plasma gas divider 145 are not numbered for the clarity of the drawings; however, they are identical to or smaller than the apertures 421, 422 and 431 to 434.

The gap between the plasma gas dividing partitions of each of the plasma gas dividers and a next one of the plasma gas dividers is smaller the better. The length L of the plasma gas mixing and distributing section 146 is ten times or more as large as the distance D between any two adjacent ones of the apertures defined in the fourth-grade plasma gas divider 145. The width W of the plasma gas mixing and distributing section 146 is marginally smaller or identical to the gap defined between the plastic coolant tank 113 and the grounded rectangular metal chamber 13.

An L-shaped high voltage isolative plate 148 is located beneath or on the plasma gas uniformly mixing and distributing section 146. The L-shaped high voltage isolative plate 148 is preferably in contact with the plastic coolant tank 113.

Two plasma gas guiding plates 149 and 150 are located on two opposite sides of the plasma gas outlet 147. The plasma gas guiding plates 149 and 150 are located as close to the plastic coolant tank 113 as possible.

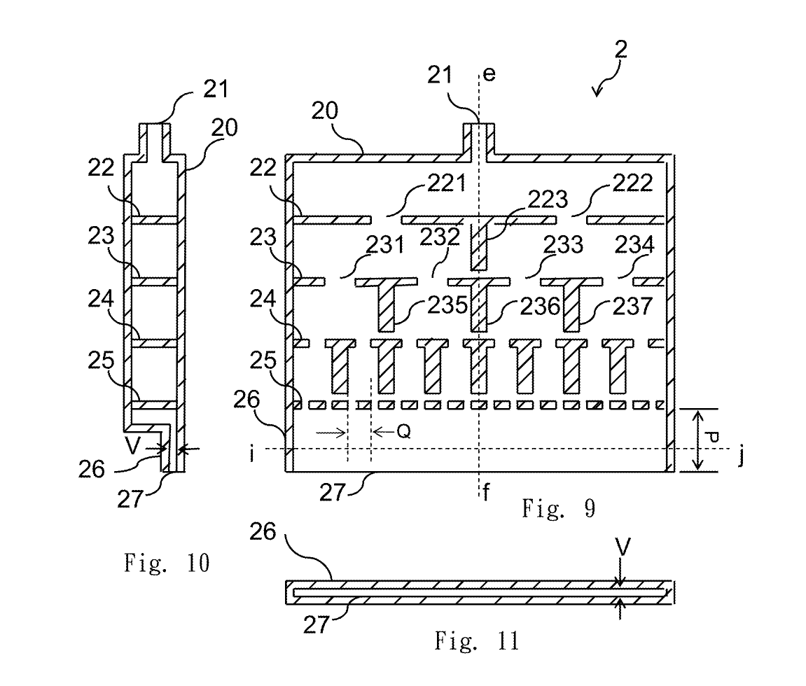

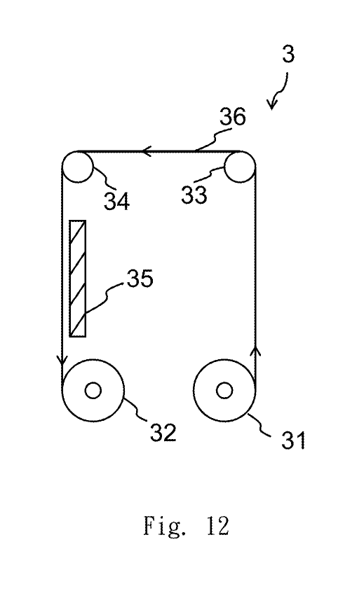

Referring to FIGS. 9 to 11, the uniform precursor distributor 2 is shown in detail. The uniform precursor distributor 2 includes a flat rectangular box 20, a first-grade precursor divider 22, a second-grade precursor divider 23, a third-grade precursor divider 24 and a fourth-grade precursor divider 25. The box 20 includes a precursor inlet 21 defined in a side, a flat precursor outlet 27 defined in an opposite side, and a flat precursor uniformly mixing and distributing section 26 defined therein near the precursor outlet 27. All of the first-grade precursor divider 22, second-grade precursor divider 23, the third-grade precursor divider 24 and the fourth-grade precursor divider 25 are located in the box 20.

The first-grade precursor divider 22 includes two identical apertures 221 and 222 defined therein and a plasma gas dividing partition 223 formed thereon between the apertures 221 and 222.

The second-grade precursor divider 23 includes four identical apertures 231, 232, 233 and 234 defined therein and three identical precursor dividing partitions 235, 236 and 237 formed thereon. Each of the precursor dividing partitions 235, 236 and 237 is located between two related ones of the apertures 231, 232, 233 and 234.

The third-grade precursor divider 24 includes eight identical apertures and seven identical precursor dividing partitions formed thereon. The apertures defined in the third-grade precursor divider 24 are not numbered for the clarity of the drawings; however, they are identical to or smaller than the apertures 221, 222 and 231 to 234. The plasma gas dividing partitions formed on the third-grade precursor divider 24 are not numbered for the clarity of the drawings; however, they are identical to the precursor dividing partitions 223 and 235 to 237. Similarly, each of the plasma gas dividing partitions formed on the third-grade precursor divider 24 is located between two related ones of the apertures defined in the third-grade precursor divider 24.

The fourth-grade precursor divider 25 includes sixteen identical apertures defined therein. The apertures defined in the fourth-grade precursor divider 25 are not numbered for the clarity of the drawings; however, they are identical to or smaller than the apertures 221, 222 and 231 to 234.

The gap between the plasma gas dividing partitions of each of the precursor dividers and a next one of the precursor dividers is smaller the better. The length P of the precursor uniformly mixing and distributing section 26 is ten times or more as large as the distance Q between any two adjacent ones of the apertures defined in the fourth-grade precursor divider 25. The width V of the precursor mixing and distributing section 26 is marginally smaller or identical to ½ of the diameter of the apertures defined in the fourth-grade precursor divider 25 to increase the speed of the precursor leaving the precursor distributor 2.

Referring to FIG. 12, the roll-to-roll substrate conveyor 3 consists of two reels 31 and 32, two positioning rollers 33 and 34 and an IR heater 35. The first reel 31 is located in the plasma activation zone. The second reel 32 is located in the plasma deposition zone. The first positioning roller 33 is located above the first reel 31 in the plasma activation zone. The second positioning roller 34 is located above the second reel 32 in the plasma deposition zone. The IR heater 35 located in the plasma deposition zone between the second reel 32 and the second positioning roller 34.

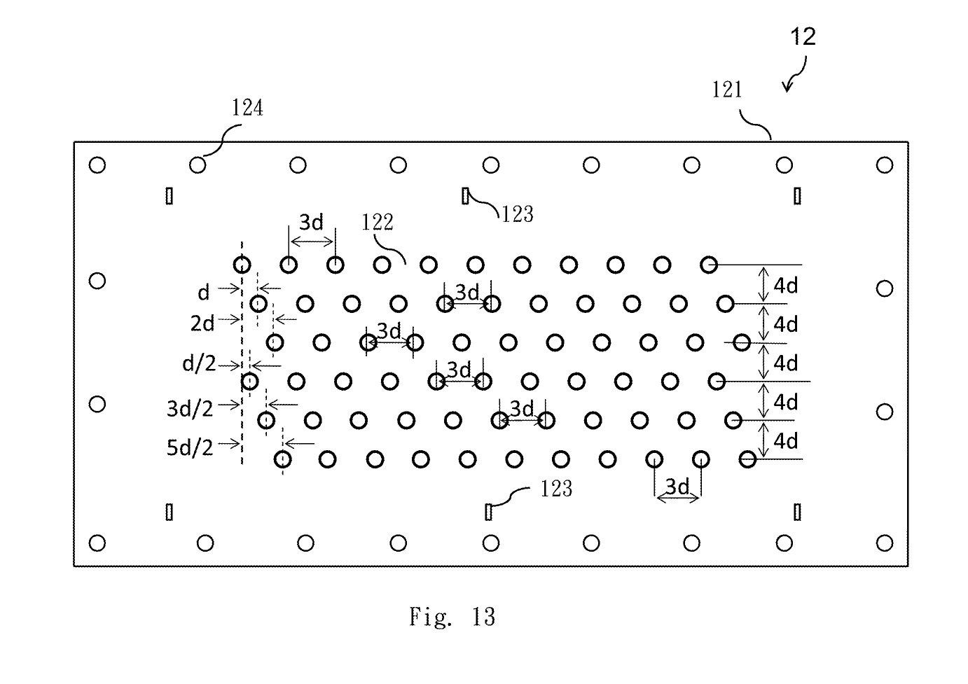

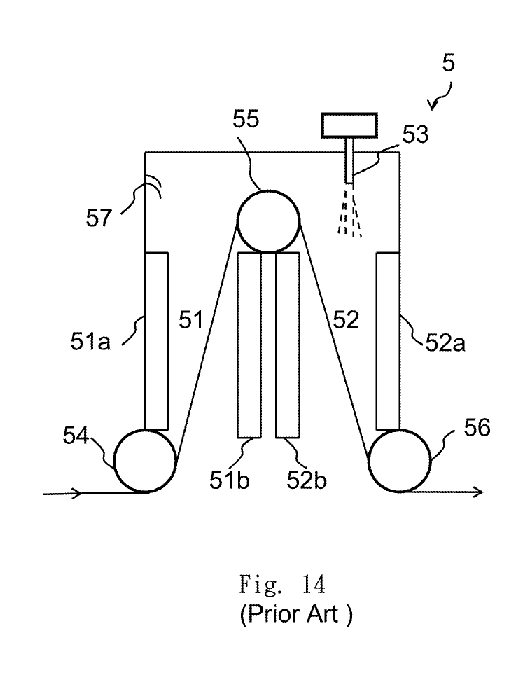

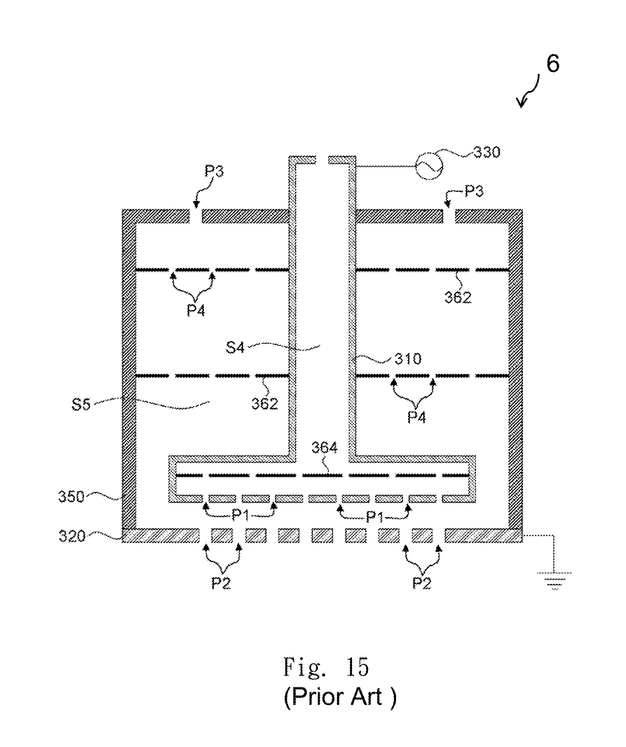

Referring to FIG. 13, the grounded planar electrode 12 includes a metal plate 121, a plasma spraying orifice array 122 evenly defined in the metal plate 12, at least six aluminum oxide ceramic pads 123 attached to the metal plate 121 around the plasma spraying orifice array 122, and a plurality of apertures or screw holes 124 defined in the metal plate 121 for receiving fasteners such as screws for attaching the metal plate 121 to the rectangular metal chamber 13 in a grounded and sealed manner. The metal plate 121 preferably includes cavities defined therein for receiving and positioning the aluminum oxide ceramic pads 123. The height of the aluminum oxide ceramic pads 123 measured from the metal plate 121 is a plasma gap of plasma discharging identical to or smaller than 0.6 mm.

The plasma spraying orifice array 122 consists of at least two plasma spraying orifice groups. Each of the plasma spraying orifice groups includes several plasma spraying orifice rows. In each of the plasma spraying orifice groups, the transverse projections of the plasma spraying orifice rows are continuous or overlap one another. In each of the plasma spraying orifice rows, the plasma spraying orifices are located evenly. For example, if the plasma spraying orifice array 122 includes two plasma spraying orifice groups, the plasma spraying orifice groups are transversely shifted from each other by ½ of the diameter d of the plasma spraying orifices. If the plasma spraying orifice array 122 includes three plasma spraying orifice groups, any two adjacent ones of the plasma spraying orifice groups are transversely shifted from each other by ⅓ of the diameter d of the plasma spraying orifices. The diameter d of the plasma spraying orifices of the plasma spraying orifice array 122 is smaller than or equal to 0.6 mm. In each of the plasma spraying orifice rows, any two adjacent ones of the plasma spraying orifices are transversely separated from each other by a distance smaller or equal to 3d. Any two adjacent ones of the plasma spraying orifice rows are separated from each other by a distance smaller than or equal to 4d. The last plasma spraying orifice row of the first plasma spraying orifice group is separated from the first plasma spraying orifice row of the second plasma spraying orifice group by a distance smaller than or equal to 4d.

The apparatus 100 of the present invention exhibits four advantageous features. At first, the gap between the electrode assemblies is small so that inexpensive nitrogen gas (N₂) can be used as the plasma gas. Secondly, the plasma is sprayed horizontally from the plasma jets of the grounded electrode assembly, and the precursor for deposition is sprayed vertically to intersect the ejected plasma jets and is decomposed by the plasma outside the grounded electrode assembly so that the interior of the N₂ plasma deposition electrode assembly would not be contaminated by the decomposed precursor. Thirdly, the plasma activation electrode assembly and the plasma deposition electrode assembly and the surface section of the substrate to be treated are positioned vertically to avoid peeled fragments of the deposition and aerosols in the deposition chamber from falling on the substrate. Fourthly, the uniform plasma gas distributor, the well overlapped plasma spraying orifices of the grounded electrode assembly and the plasma spraying orifices of the long-line uniform precursor distributor make it possible to execute excellent and uniform large area plasma deposition. The apparatus 100 of the present invention overcome the problems addressed in the Related Prior Art.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. An large area atmospheric pressure plasma enhanced chemical vapor deposition apparatus including:
a sub-atmospheric pressure deposition chamber 4 including a vent 41 defined therein and a pump 42 operable for pumping gas from the sub-atmospheric pressure deposition chamber 4 through the vent 41 to create a sub-atmospheric pressure condition in the sub-atmospheric pressure deposition chamber 4;
at least one large area vertical planar atmospheric pressure N₂ plasma activation electrode assembly 1a located in the sub-atmospheric pressure deposition chamber 4;
a first high voltage power supply 5a located outside the sub-atmospheric pressure deposition chamber 4 and electrically connected to the large area vertical planar atmospheric pressure N₂ plasma activation electrode assembly 1a;
at least one large area vertical planar atmospheric pressure N₂ plasma deposition electrode assembly 1b located in the sub-atmospheric pressure deposition chamber 4;
a second high voltage power supply 5b located outside the sub-atmospheric pressure deposition chamber 4 and electrically connected to the large area vertical planar atmospheric pressure N₂ plasma deposition electrode assembly 1b;
at least one long-line uniform precursor distributor 2 located in the sub-atmospheric pressure deposition chamber 4 between the large area vertical planar atmospheric pressure N₂ plasma deposition electrode assembly 1b and a second vertical section of a substrate and connected to a precursor provider 201 located outside the sub-atmospheric pressure deposition chamber 4; and
a roll-to-roll substrate conveyor 3 located in the sub-atmospheric pressure deposition chamber 4 for conveying the substrate so that the first vertical section of the substrate travels past the large area vertical planar atmospheric pressure plasma activation electrode assembly 1b while a second vertical section of the substrate travels past the large area vertical planar atmospheric pressure plasma deposition electrode assembly 1a.

2. The large area atmospheric pressure plasma enhanced chemical vapor deposition apparatus according to claim 1, wherein each of the large area vertical planar atmospheric pressure N₂ plasma activation and deposition electrode assemblies 1a, 1b includes:
a grounded and sealed rectangular metal chamber 13;
a grounded planar electrode 12 located on the rectangular metal chamber 13;
a water-cooled planar high voltage electrode 11 located in the rectangular metal chamber 13; and
two uniform plasma gas distributors 14, 15 located above and below the planar high voltage electrode 11, respectively.

3. The large area atmospheric pressure plasma enhanced chemical vapor deposition apparatus according to claim 2, wherein the planar high voltage electrode 11 includes:
a rectangular metal plate 111;
an aluminum oxide ceramic dielectric plate 112 attached to a rectangular metal plate 111;
a plastic coolant tank 113 located around and attached to the aluminum oxide ceramic dielectric plate 112;
a high voltage connecting rod 114 inserted through the plastic coolant tank 113 and connected to the metal plate 111;
a high voltage isolative sleeve 115 located around the high voltage connecting rod 114; and
a coolant channel 116 defined in the plastic coolant tank 113.

4. The large area atmospheric pressure plasma enhanced chemical vapor deposition apparatus according to claim 2, wherein the rectangular metal chamber 13 includes coolant inlet and outlet 131, 132 defined therein and two plasma gas inlet pipes 133, 134 inserted therein.

5. The large area atmospheric pressure plasma enhanced chemical vapor deposition apparatus according to claim 2, wherein the grounded planar electrode 12 includes:
a rectangular metal plate 121 including a plasma spraying orifice array 122 evenly defined therein;
a plurality of aluminum oxide ceramic pads 123 attached to the rectangular metal plate 121 around the plasma spraying orifice array 122;
and a plurality of apertures or screw holes 124 defined in the metal plate 121 for receiving fasteners such as screws for attaching the metal plate 121 to the four neighboring metal plates of the rectangular metal chamber 13.

6. The large area atmospheric pressure plasma enhanced chemical vapor deposition apparatus according to claim 5, wherein the plasma spraying orifice array 122 includes at least two plasma spraying orifice groups each including several plasma spraying orifice rows, wherein transverse projections of the plasma spraying orifice rows are overlapped well one another in each of the plasma spraying orifice groups.

7. The large area atmospheric pressure plasma enhanced chemical vapor deposition apparatus according to claim 6, wherein the plasma spraying orifice array 122 includes two plasma spraying orifice groups, wherein the plasma spraying orifice groups are transversely shifted from each other by ½ of the diameter d of the plasma spraying orifices.

8. The large area atmospheric pressure plasma enhanced chemical vapor deposition apparatus according to claim 6, wherein the plasma spraying orifice array 122 includes three plasma spraying orifice groups, wherein any two adjacent ones of the plasma spraying orifice groups are transversely shifted from each other by ⅓ of the diameter d of the plasma spraying orifices.

9. The large area atmospheric pressure plasma enhanced chemical vapor deposition apparatus according to claim 2 wherein each of the uniform plasma gas distributors 14, 15 includes:
a flat box 141 including a plasma gas inlet 140 defined in a side, a plasma gas outlet 147 defined in an opposite side, and a plasma gas uniformly mixing and distributing section 146 defined therein near the plasma gas outlet 147;
a first-grade plasma gas divider 142 located in the flat rectangular box 141 for dividing plasma gas to two streams;
a second-grade plasma gas divider 143 located in the flat rectangular box 141 for dividing the plasma gas into four streams;
a third-grade plasma gas divider 143 located in the flat rectangular box 141 for dividing the plasma gas into eight streams; and
a fourth-grade plasma gas divider 145 located in the flat rectangular box 141 for dividing plasma gas into sixteen streams.

10. The large area atmospheric pressure plasma enhanced chemical vapor deposition apparatus according to claim 9, wherein each of the uniform plasma gas distributors 14, 15 includes:
a high voltage isolative plate 148 located beneath or on the plasma gas mixing and distributing section 146; and
two plasma gas confinement plates 149, 150 located on two opposite sides of the plasma gas outlet 147.

11. The large area atmospheric pressure plasma enhanced chemical vapor deposition apparatus according to claim 9, wherein the long-line uniform precursor distributor 2 includes:
a flat box 20 including a precursor inlet 21 defined in a side, a precursor outlet 27 defined in an opposite side, and a flat precursor uniformly mixing and distributing section 26 defined therein near the precursor outlet 27;
a first-grade precursor divider 22 located therein for dividing precursor into two streams;
a second-grade precursor divider 23 located therein for dividing the precursor into four streams;
a third-grade precursor divider 24 located therein for dividing the precursor into eight streams; and
a fourth-grade precursor divider 25 located therein for dividing the precursor into sixteen streams.

12. The large area atmospheric pressure plasma enhanced chemical vapor deposition apparatus according to claim 1, wherein the roll-to-roll substrate conveyor 3 includes:
a first reel 31 located near the large area vertical planar atmospheric pressure N₂ plasma activation electrode assembly 1a;
a second reel 32 located near the large area vertical planar atmospheric pressure N₂ plasma deposition electrode assembly 1b;
a first positioning roller 33 located above the first reel 31;
a second positioning roller 34 located above the second reel 32;
an IR heater 35 located between the second reel 32 and the second positioning roller 34.

13. The large area atmospheric pressure plasma enhanced chemical vapor deposition apparatus according to claim 1, wherein each of the high voltage power supplies 5a, 5b is selected from the group consisting of a high voltage pulse power supply, high voltage sinusoidal power supply and a high power RF power supply operated at 1 to 100 kHz.
